(19) United States
(12) Patent Application Publication
(10) Pub. No.: US 2025/0175138 A1
(43) Pub. Date: May 29, 2025

(54) STRUCTURE FOR PENETRATING ACOUSTIC BARRIER IN A BROADBAND FREQUENCY RANGE

(71) Applicant: KOREAN ADVANCED INSTITUTE OF SCIENCE AND TECHNOLOGY, Daejeon (KR)

(72) Inventors: Wonju JEON, Daejeon (KR); Junyong AN, Daejeon (KR); Kiyong LEE, Daejeon (KR); Chankyu KIM, Daejeon (KR)

(21) Appl. No.: 18/957,145

(22) Filed: Nov. 22, 2024

(30) Foreign Application Priority Data
Nov. 24, 2023 (KR) 10-2023-0165813

(51) Int. Cl. H03H 9/00; H03H 9/02

(52) U.S. Cl. CPC H03H 9/0014; H03H 9/0211

(57) ABSTRACT

The present disclosure relates to a structure attached to front interface for acoustic barrier penetration in broadband frequency range and, in more detail, relates to a structure that is composed of an impedance matching layer minimizing wave energy reflection between a background medium and an acoustic barrier and a wave interference control layer for controlling multiple reflection in the acoustic barrier and is attached to a front surface of an acoustic barrier, thereby being able to improve convenience and implement high transmittance in a wide frequency band.

### CROSS-REFERENCE TO RELATED APPLICATION

This application claims priority under 35 U.S.C. § 119 to Korean Patent Application No. 10-2023-0165813, filed on Nov. 24, 2023, in the Korean Intellectual Property Office, the disclosure of which is incorporated herein by reference in its entirety for all purposes.

### TECHNICAL FIELD

The following disclosure relates to structure for penetrating acoustic barrier in a broadband frequency range, which can improve convenience and can implement high transmittance in a wide frequency band because the structure is disposed only on an incident surface of an incident surface and a transmission surface of an acoustic barrier.

### BACKGROUND

FIG. 1 is a conceptual diagram of a sound wave traveling into an acoustic barrier. As illustrated in (a) of FIG. 1, when a sound wave that has passed through a medium such as air or water travels into an acoustic barrier (a substance having a high impedance value in comparison to the background medium), most of acoustic energy is reflected due to impedance mismatch of the acoustic barrier and the background medium.

As the existing techniques for reducing reflection by an acoustic barrier and enhancing the transmittance of transmitted acoustic energy, there are an impedance matching layer shown in (b) of FIG. 1, a complementary metamaterial shown in (c) of FIG. 1, etc.

However, an impedance matching layer has a problem: it has to be attached to both the two interfaces between background media and acoustic barrier, as illustrated in (b) of FIG. 1, and a complementary metamaterial has limitation that the operation frequency band of high transmittance (e.g., transmittance over 0.7) is very narrow, as illustrated in (c) of FIG. 1.

Accordingly, there is a need for a new technology for solving these problems.

### RELATED ART DOCUMENT

### Patent Document

(Patent Document 1) Korean Patent Publication No. 10-2354340 (registered on Jan. 18, 2022)

### SUMMARY

An embodiment of the present disclosure is directed to providing a structure that is more convenient to use and can implement high transmittance at a wide frequency band because the structure is disposed only on an incident surface of the incident surface and a transmission surface of an acoustic barrier.

In one general aspect, there is a structure that is attached to a front surface of an acoustic barrier for high transmittance, the structure including:

an impedance matching layer for transmitting a wave through the acoustic barrier by minimizing reflection of the wave due to the impedance mismatch between the acoustic barrier and an incident medium; and

a wave interference control layer for controlling interference due to multiple reflections within the acoustic barrier.

The impedance matching layer and the wave interference control layer may have been staked in the traveling direction of the wave, and the structure may be configured such that the wave sequentially passes through the impedance matching layer, the wave interference control layer, and the acoustic barrier.

The wave interference control layer may be attached to a front surface of the acoustic barrier.

The wave interference control layer may be located at a predetermined distance from the front surface of the acoustic barrier.

The impedance matching layer and the wave interference control layer each may be configured in a structure in which at least one or more void is formed in a base matrix.

The void of the impedance matching layer may be formed in a structure that is symmetric with respect to a center line of the impedance matching layer.

The void of the impedance matching layer may be formed in a structure that is asymmetric with respect to a center line of the impedance matching layer.

The void of the wave interference control layer may be formed in a structure that is symmetric with respect to a center line of the wave interference control layer.

The void of the wave interference control layer may be formed in a structure that is asymmetric with respect to a center line of the wave interference control layer.

The structures of the impedance matching layer and the wave interference control layer each may be designed on the basis of a topology optimization algorithm.

The structures of the impedance matching layer and the wave interference control layer each may be designed using the following equation,

$$G = {\sum }_{n = 1}^{∞} {\vert \frac{{I}_{t}}{{I}_{i}} \vert}_{f - {f}_{n}} \qquad [ Equation ]$$

(where, G is an objective function, Iᵢ is acoustic intensity of an incident wave, Iₜ is acoustic intensity of a transmission wave, f is a frequency of the incident wave, and fₙ is

$$\frac{( n - 1 ) ( {f}_{e} - {f}_{s} )}{n}$$

where fₛ and fₑ are start and end frequencies of the target frequency band).

The void may be filled with air or other materials.

The impedance matching layer and the wave interference control layer each may be configured in a structure of which a predetermined horizontal cross-sectional shape extends in a height direction.

The base matrix may be made of a material the same as the acoustic barrier.

The base matrix may be made of a material different from the acoustic barrier.

The impedance matching layer and the wave interference control layer may be attached only to the front surface of the acoustic barrier and may not be installed on a rear surface of the acoustic barrier.

The present disclosure provides a method of designing the structure that includes: a first step of designing the impedance matching layer through a topology optimization; and a second step of designing the wave interference control layer through the topology optimization.

The method may further include a redesign step of correcting an initial design of the impedance matching layer obtained through the first step in consideration of input impedance at the incident interface.

In the redesign step, an initial design of the impedance matching layer designed in the first step may be set as an initial design and a final design of the impedance matching layer may be designed through a topology optimization.

### BRIEF DESCRIPTION OF THE DRAWINGS

FIG. 1 is a conceptual diagram of a sound wave traveling into an acoustic barrier.

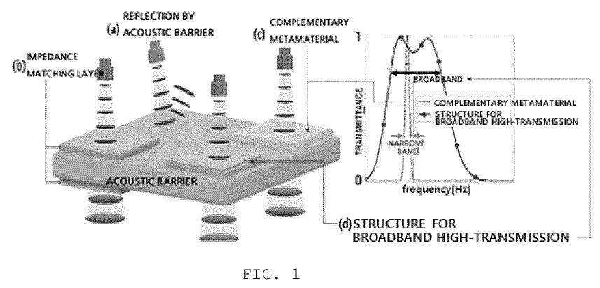

FIG. 2 is a view showing a structure attached to the acoustic barrier according to an embodiment of the disclosure.

FIG. 3 is a view showing the structure for high transmission in a broadband frequency range according to an embodiment of the disclosure.

FIG. 4 is a view illustrating a process of designing an impedance matching layer.

FIG. 5 is a view showing transmission performance of the impedance matching layer of FIG. 4.

FIGS. 6A and 6B are views illustrating a process of designing a wave interference control layer.

FIG. 7 is a view showing transmission performance of the wave interference control layer of FIG. 6.

FIGS. 8A and 8B are views illustrating a final process of designing the structure.

FIG. 9 is a view showing transmission performance of the structure of FIGS. 8A and 8B.

FIGS. 10A and 10B are views illustrating the structure according to a second example of the present disclosure.

FIGS. 11A and 11B are views illustrating the structure according to the first example and the structure according to the second example of the present disclosure.

FIGS. 12A and 12B are views illustrating the structure according to a third example of the present disclosure.

FIGS. 13A and 13B are views illustrating the structure according to a fourth example of the present disclosure.

FIG. 14 is a view showing an application example of the present disclosure.

### DETAILED DESCRIPTION OF MAIN ELEMENTS

10: Structure for penetrating acoustic barrier in a broadband frequency range
100: Impedance matching layer
110: Base matrix of impedance matching layer
120: Void of impedance matching layer
200: Wave interference control layer
210: Base matrix of wave interference control layer
220: Void of wave interference control layer
MD: Background medium
BA: Acoustic barrier

### DETAILED DESCRIPTION OF EMBODIMENTS

Hereinafter, the present disclosure is described with reference to the accompanying drawings.

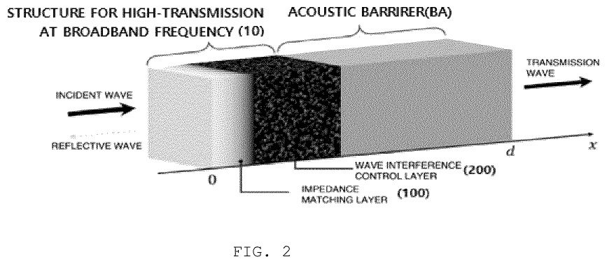

FIG. 2 is a view showing a structure attached to an acoustic barrier according to an embodiment of the disclosure. The structure of the present disclosure is a broadband high-transmission structure and may correspond to a kind of metamaterial.

As shown in the figure, a structure 10 for high transmittance within broadband frequency range is located at the front surface of an acoustic barrier BA. Incident acoustic wave penetrates the barrier due to the structure which matches input impedance at the incident interface with impedance of incident medium.

The structure 10 includes, in a broad meaning, an impedance matching layer 100 and a wave interference control layer 200. The impedance matching layer 100 performs a function of improving transmission of a wave into an acoustic barrier by minimizing reflection by the acoustic barrier and the wave interference control layer 200 performs a function of controlling interference by multiple reflections within the acoustic barrier.

In more detail, impedance mismatching between an acoustic barrier and a background medium and a phase difference of a sound wave traveling into and passing through the acoustic barrier influence the transmission loss of wave energy, but the structure of the present disclosure is designed to cancel out these two influences, and accordingly, it is possible to enhance acoustic energy that has passed through an acoustic barrier, as compared with when there is no structure.

Referring to FIG. 2 again, the impedance matching layer 100 and the wave interference control layer 200 may have been stacked in the traveling direction of a wave. That is, the impedance matching layer 100 and the wave interference control layer 200 may be configured each in a block type in close contact with each other. The impedance matching layer 100 and the wave interference control layer 200 may be separately configured or may be integrally configured. Due to this configuration, a wave sequentially passed through the impedance matching layer 100, the wave interference control layer 200, and the acoustic barrier BA.

In this configuration, the structure 10 may be installed ahead of the acoustic barrier BA at a predetermined distance forward from the front surface of the acoustic barrier BA or may be attached to the front surface of the acoustic barrier BA. However, it would be more preferable to attach the structure 10 to the front surface of the acoustic barrier BA in terms of improvement of transmittance.

Further, the impedance matching layer 100 and the wave interference control layer 200, that is, the structure 10 is installed only on the front surface of the acoustic barrier BA and is not installed on the rear surface of the acoustic barrier BA. In other words, the structure 10 of the present disclosure is attached to the front surface of the acoustic barrier BA and installed ahead of the acoustic barrier in the traveling direction of a wave.

It is possible to increase the transmittance of wave by installing a structure for broadband high-transmission only on the front surface of an acoustic barrier in the present disclosure, as described above, and, for example, when it is difficult to attach the structure the rear surface of an acoustic barrier such as the skull, it is possible to enhance an acoustic transmittance by installing the structure of the present disclosure on the front surface of the skull and accordingly it may increase the possibility of observing the inside of the skull.

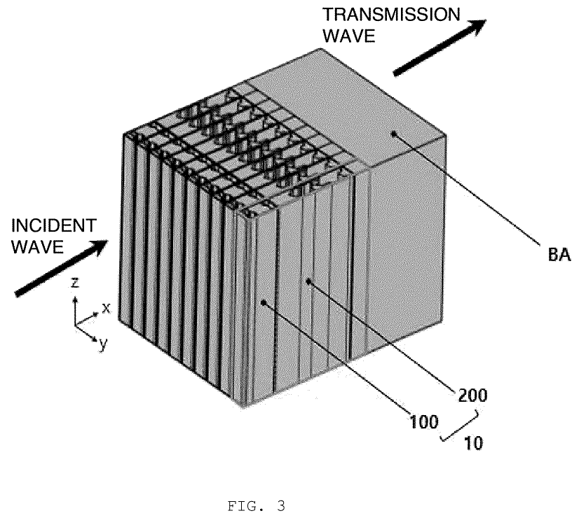

FIG. 3 is a view showing structure according to an embodiment of the present disclosure, and, as shown in the figure, the structure 10 may be disposed ahead of an acoustic barrier BA. In more detail, the structure 10 may be composed of multiple layers and configured as an assembly, and the structures 10 may be repeatedly arrayed in parallel in a width direction (the y direction in the figure), and each of the structures 10 may be configured in a structure in which a predetermined horizontal cross-sectional shape (the cross-sectional shape of an xy plane in the figure) in the height direction (z direction in the figure).

Hereafter, the structure of the structure of the present disclosure and a designing method thereof are described in more detail.

A theoretical condition for perfect transmission of a wave passing through the structure and an acoustic barrier is described as the following Equation 1.

$${[ \begin{matrix}p \\ u\end{matrix} ]}_{x = 0} = {T}_{L} {{T}_{B} [ \begin{matrix}p \\ u\end{matrix} ]}_{x = d} = {1 [ \begin{matrix}p \\ u\end{matrix} ]}_{x = d} = {[ \begin{matrix}p \\ u\end{matrix} ]}_{x = d} \qquad [ Equation 1 ]$$

Equation 1 shows the relationship between a pressure filed p and a velocity field u on the structure surface (x=0) of an incident region and an acoustic barrier surface (x=d) of a transmission region. T_{L} is a transfer matrix of the structure, T_{B} is a transfer matrix of the acoustic barrier, T₁ is a transfer matrix of impedance matching layer (hereafter, also referred to as a ‘matching layer’), and T₂ is a transfer matrix of wave interference control layer (hereafter, also referred to as a ‘control layer’), in which the transfer matrix T_{L} of the structure may correspond to the product of the transfer matrix T₁ of the matching layer and the transfer matrix T₂ of the control layer (T_{L}=T₁T₂).

A vector composed of two physical quantities p and u should be matched in an incident region and a transmission region for perfect transmission of wave energy, which means that the product of the transfer matrix T_{L}=T₁T₂ of the structure and the transfer matrix T_{B} of the acoustic barrier should result in the identity matrix (I). According to the present disclosure, it is possible to design a matching layer and a control layer such that the transfer matrix of the structure becomes the inverse matrix of the transfer matrix of an acoustic barrier.

The matching layer and the control layer each have a structure in which at least one or more voids are included in a base matrix, and the number and shape of the voids may depend on selection of the substance constituting the base matrix. The void may be filled with air or other materials.

It is recommended to select a substance having a small impedance difference from the acoustic barrier as the constituent material of the base matrix, and the base matrix of the matching layer and the base matrix of the control layer do not necessarily have to be the same. That is, the base matrix of the matching layer and the base matrix of the control layer may be made of the same substance or different substance, and at the same time and separately, they each may be made of a substance the same as or different from the substance of the acoustic barrier. However, it would be preferable to use the same substance for the matching layer, the control layer, and the acoustic barrier in terms of improvement of transmittance.

Hereafter, an example of designing a structure for high transmission in a broadband frequency range, for example, under the assumption that the base matrix of an impedance matching layer and the base matrix of a wave interference control layer are the same as aluminum (Al), the void in the base matrix of each of the layers is air, and the background medium (MD) is water.

Assuming that an ultrasound wave of around 50 kHz travels into an acoustic barrier with a length of 25 mm in the water that is the background medium, the acoustic impedance of aluminum is very high as about 11 times the acoustic impedance of water, so acoustic energy of over 99% is reflected due to impedance mismatching. An object of the present disclosure is to implement high transmittance (over 0.7) by installing the structure in this situation.

The present disclosure can design a matching layer as a first step, design a control layer as a second step, and design the structure by redesigning the impedance matching layer designed in the first step.

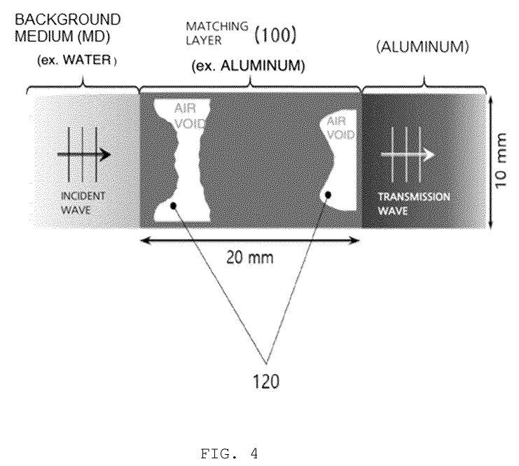

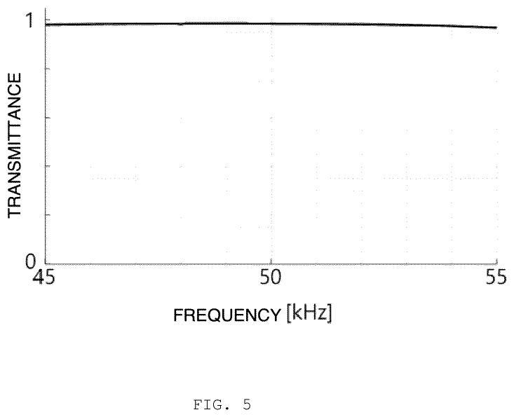

FIG. 4 is a view illustrating the result of designing an impedance matching layer and FIG. 5 is a view showing transmission spectrum of the impedance matching layer of FIG. 4. The first layer, that is, the matching layer of the structure proposed in the present disclosure serves to reduce reflection on an incident surface and increase transmission of wave energy into an acoustic barrier. In order to design a matching layer, a topology optimization technique based on a method of moving asymptotes (MMA) may be used and may be performed through a processor.

Referring to FIG. 4, in the present disclosure, a matching layer is designed such that the transmittance of wave energy that is transmitted into the acoustic barrier is maximized. In more detail, topology optimization for the objective function G of the following Equation 2 to have a maximum value is performed and a condition for symmetry from the center line of the matching layer may be selectively given.

$$G = {\sum }_{n = 1}^{∞} {\vert \frac{{I}_{t}}{{I}_{i}} \vert}_{f - {f}_{n}} \qquad [ Equation 2 ]$$

(where, G is an objective function, Iᵢ is the acoustic intensity of an incident wave, Iₜ is the acoustic intensity of a transmission wave, fis the frequency of the incident wave, and fₙ is

$$\frac{( n - 1 ) ( {f}_{e} - {f}_{s} )}{n}$$

where fₛ and fₑ are start and end frequencies of the target frequency band).

In this example, f₁=47.5 kHz, f₂=50 kHz, f₃=52.5 kHz in consideration of that the target center frequency is 50 kHz and the bandwidth to the center frequency is 10%. It is assumed that the initial design of the matching layer is set as a complete aluminum plate without air void and the boundary of designing regions is a solid to prevent an extreme situation in which a wave is not transmitted due to disconnection between media. The optimally tolerance value used in the process of topology optimization is 0.001 and the size of meshes used for acoustic analysis is 0.5 to 1 mm.

As the result of performing a topology optimization process for satisfying the initial conditions described above and maximizing the objective function G, as illustrated in FIG. 4, a unit structure of a matching layer 100 including closed curve air voids 120 having areas of 28.1 mm² and 19.3 mm² in an aluminum base matrix 1110 of 20×10 mm² is designed. It can be seen that the input impedances at the incident interface are the same as that of water in the designed matching layer (Zs=Zwater) in a frequency band of 45 to 55 kHz, so the transmittance in the frequency band is close to 1, as illustrated in FIG. 5.

Meanwhile, the matching layer helps wave energy be transmitted into the acoustic barrier by minimizing reflection of a wave on the interface between the background medium (water) and the acoustic barrier (aluminum) in the incident region, but it impossible to control multiple reflection that is generated on the interface between the acoustic barrier and the background medium (water) of the transmission region, so it is difficult to expect high transmittance of wave energy from only the matching layer. Accordingly, in the present disclosure, a wave interference control layer for increasing the transmittance of wave energy by controlling interference due to multiple reflection on a barrier is additionally designed.

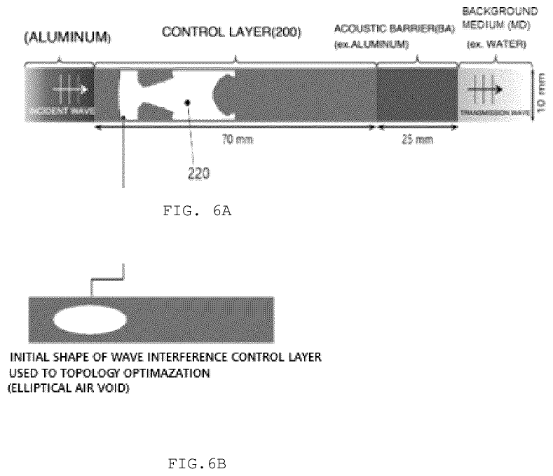

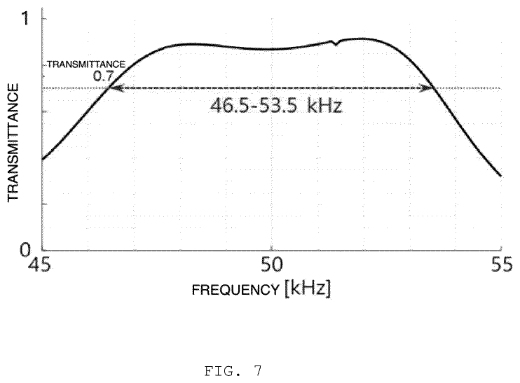

FIGS. 6A and 6B are views illustrating a process of designing a wave interference control layer and FIG. 7 is a view showing transmission performance of the wave interference control layer of FIGS. 6A and 6B. Referring to FIGS. 6A and 6B, it is assumed that an aluminum medium constituting a matching layer is disposed ahead of a control layer and plane wave generated from the aluminum medium is transmitted to the background medium (water) of a transmission region through the control layer and an acoustic barrier. The objective function, maximum optimally tolerance, and the grid size that are used in topology optimization for designing the control layer are the same as the values used in the previous process of designing an impedance matching layer, and similar to the matching layer, a topology optimization technique based on MMA may be used to design the control layer, and the condition of up-down symmetry from the center of the control layer may be selectively given.

First, as illustrated in FIG. 6B, a structure in which an elliptical air void is included in an aluminum plate may be set as the initial design of a wave interference control layer. Further, as the result of performing topology optimization through a processor on the basis of Equation 2, as illustrated in FIG. 6A, a unit structure of a control layer 200 including a closed curve air void 220 having an area of 179 mm² at the center of an aluminum base matrix 210 of 70×10 mm² is designed. The control layer controls interference due to multiple reflection that is generated at the boundary between the background medium and the water in the transmission region of the acoustic barrier, and accordingly, it can be seen that transmittance of over 70% is derived in a wide frequency band of 46.5 to 53.5 kHz, as illustrated in FIG. 7.

It is possible to obtain initial design the structure by combining the matching layer and the control layer designed through two processes, as described above. However, in the process of combining two layers, that is, the matching layer and the control layer, the wave characteristics at the layers influence each other, so there is a need for additional work for correcting the influence. In particular, the input impedance at the incident interface is not the same as that of water due to existence of the control layer (Zs≠Zwater), so reflection on the interface between the medium and the structure in the incident region is necessarily generated. Accordingly, there is a need for a process of partially correcting the structure of the initially designed matching layer.

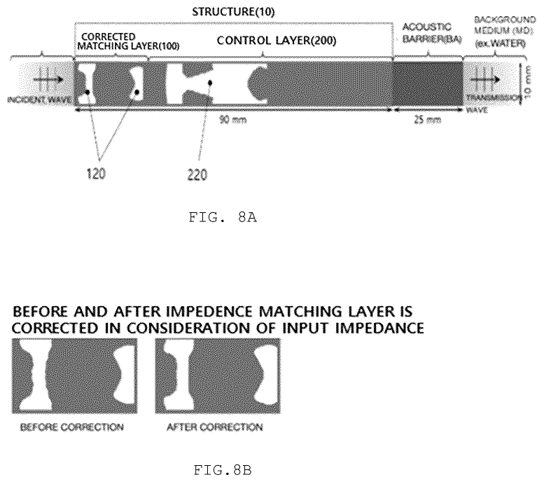

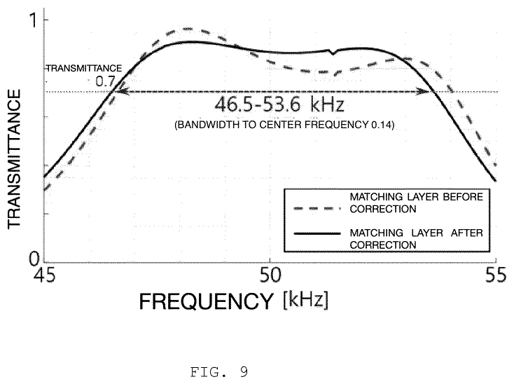

FIGS. 8A and 8B are views illustrating a final process of designing a structure for high transmittance in a broadband frequency range and FIG. 9 is a view showing transmission performance of the structure of FIGS. 8A and 8B.

The present disclosure can obtain a corrected version of a matching layer, as in the right one in FIG. 8B, by setting an initial matching layer design structure obtained in the previous designing process as an initial design, as in the left one in FIG. 8B, and then performing again the topology optimization process. The topology optimization process in this step may be performed under the same conditions as the process of designing a matching layer or a control layer described above, and, similar to designing of the matching layer or the control layer, it is apparent that the topology optimization process may be performed using the topology optimization technique based on MMA.

FIG. 8A shows a final design of the structure 10, which are composed of air voids 120 and 220 having areas of 27.3 mm², 21.5 mm², and 179 mm² in aluminum base matrixes 110 and 210 of 90×10 mm². It can be seen that when the structure is attached to an acoustic barrier with 25 mm positioned in water that is a background material, as illustrated in FIG. 9, wave energy transmission of over 70% is implemented in a frequency band of 46.5 to 53.6 kHz.

This is a bandwidth of the ratio of about 0.14 to the center frequency of 50 kHz and it can be seen that the structure of the present disclosure is remarkably improved in terms of broadband and high transmission in consideration of that the transmission bandwidths of barrier transmission technologies of the related art such as a complementary metamaterial are about 0.01 to the center frequency.

The method of designing the structure of the present disclosure described above can be summarized as follows.
1. Designing of an impedance matching layer that minimizes wave energy reflection between a background medium and an acoustic barrier (first step)
2. Designing of a wave interference control layer for controlling multiple reflection on the acoustic barrier (second step)
3. Correcting of design of the matching layer in consideration of input impedance at the incident interface (third step)
4. Completion of final designing of the structure in which the corrected matching layer and the control layer are combined.

Meanwhile, it was described that the structure according to an example of the present disclosure has an up-down symmetric structure from the center of the structure (hereafter, also referred to as a symmetric structure), but the structure is not limited to specific materials and shape and structures made of various materials and having various shapes are described hereafter through embodiments.

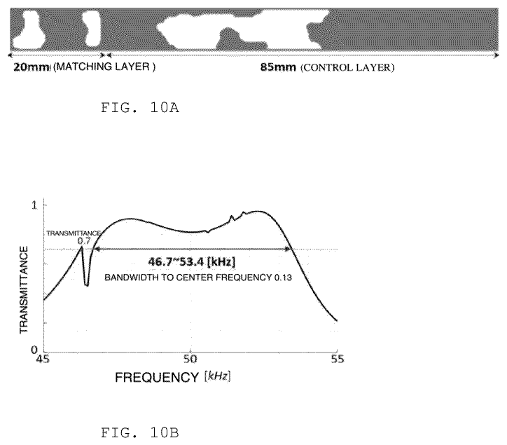

Referring to FIGS. 8A and 8B, a structure according to a first embodiment of the present disclosure may be designed symmetrically about the center line of the structure. Meanwhile, referring to FIGS. 10A and 10B, a structure according to a second embodiment of the present disclosure may be designed asymmetrically about the center line of the structure (hereafter, also referred to an asymmetric structure).

However, when a structure is designed to have void of a structure that is symmetric up and down with respect to the center line of the structure, it may be preferable in terms of convenience of manufacture. When a structure is designed to have void that is not symmetric up and down, it may be preferable in that it is possible to obtain various designs because the degree of freedom in designing is improve even though the convenience of manufacturing is slightly deteriorated. Accordingly, users can selectively design and apply desired structures from a symmetric structure and an asymmetric structure.

As described above, when a structure is designed without a restriction condition that the structure is symmetric up and down with respect to the center of the structure, the degree of freedom in design is increased, so various designs can be obtained, and a final design structure of the structure according to the second embodiment of the present disclosure is shown in FIG. 10A.

A matching layer has asymmetric air voids having areas of 39.2 mm² and 25.6 mm² in an aluminum base matrix of 20×10 mm², and a control layer has an asymmetric air void having an area of 235 mm² in an aluminum base matrix of 85×10 mm². When the structure designed as described above is attached to the front surface of an aluminum barrier having a thickness of 25 mm, it can be seen that it is possible to obtain transmittance of over 70% in a band of 46.7˜53.4 kHz, as illustrated in FIG. 10B.

That is, even though an asymmetric structure is applied, transmittance similar to that of a symmetric structure can be obtained, so user can selectively apply a symmetric structure and an asymmetric structure by comparing the convenience of manufacturing and the freedom of designing, depending on cases.

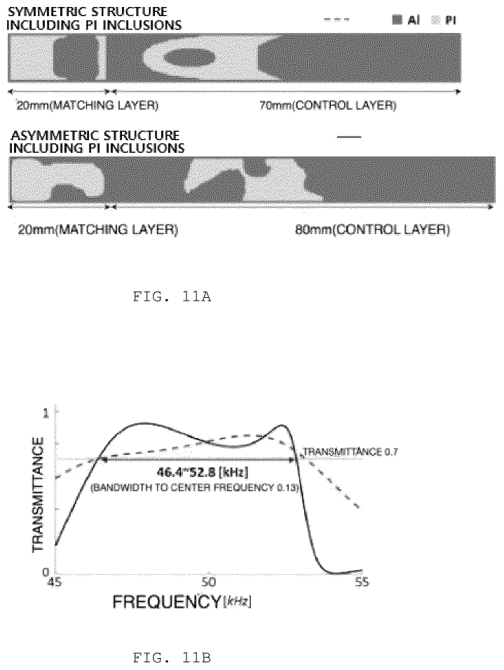

FIG. 11A is a view illustrating the structure according to the first embodiment and the structure according to the second embodiment of the present disclosure and shows the case when air voids of the structures according to the first and second embodiment have been replaced with polyimide (PI) inclusions. When an air void is included in a structure, there is a very thin portion where the thickness of an aluminum base matrix is hundreds of μm, so damage due to external shock may be generated, but when void is replaced with a solid inclusion, as in this example, there is the advantage that the structural vulnerability can be complemented.

As the result of performing the same topology optimization described above, a structure composed of a matching layer in which PI inclusions having areas of 79.3 mm² and 14.8 mm² are included in an aluminum base matrix of 20×10 mm² and a control layer in which a PI inclusion having an area of 156 mm² is included in an aluminum base matrix of 70×10 mm² is designed, such as the symmetrical structure shown at the upper portion in FIG. 11A.

Meanwhile, a structure composed of a matching layer in which a PI inclusion having an area of 125 mm² is included in aluminum base matrixes having sizes of 20×10 mm² and 80×10 mm² and a control layer in which a PI inclusion having an area of 143 mm² in an aluminum base matrix is designed, such as the asymmetric structure shown at the lower portion in FIG. 11A.

When the structure of this example composed of aluminum and PIs is attached to a barrier of 25 mm positioned in water that is a background medium, as illustrated in FIG. 11B, it can be seen that transmittance of over 70% is implemented in a frequency band of 46.4 to 52.8 kHz.

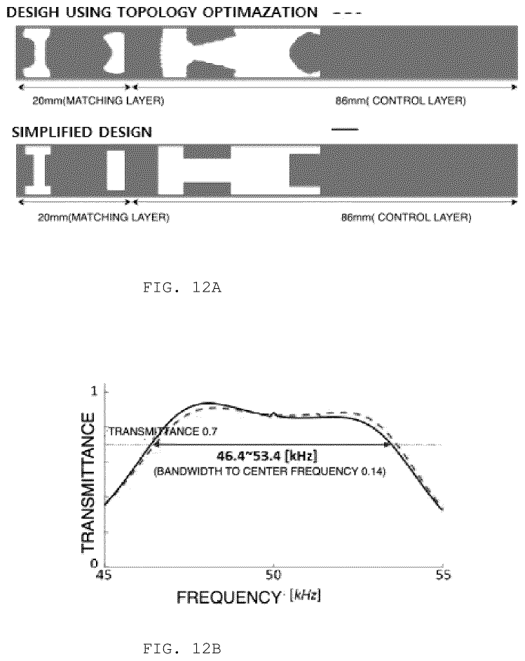

FIGS. 12A and 12B are views illustrating a structure according to a third example of the present disclosure. This example corresponds to the case when an air void has been replaced with a polygon. Since the size of the minimum line width of the closed curve air void of the structure described above is very small as 0.5 mm, a very delicate processing technique is required or a manufacturing error has to be accepted for manufacturing. Accordingly, design was complemented by a polygonal air void that is similar in shape and area to a closed curve air void in order to increase the convenience of manufacturing and minimize the manufacturing error.

It was found that the structure of this example, as illustrated in FIG. 12B, has transmittance performance of over 70% at 46.4 to 53.4 kHz and the average transmittance is about 85%. This means that even through the shape of void having a closed curve shape designed through topology optimization is simplified into a polygon, the transmission performance of the structure is maintained and at the same time, the structure of the present disclosure is not greatly sensitive to a manufacturing error.

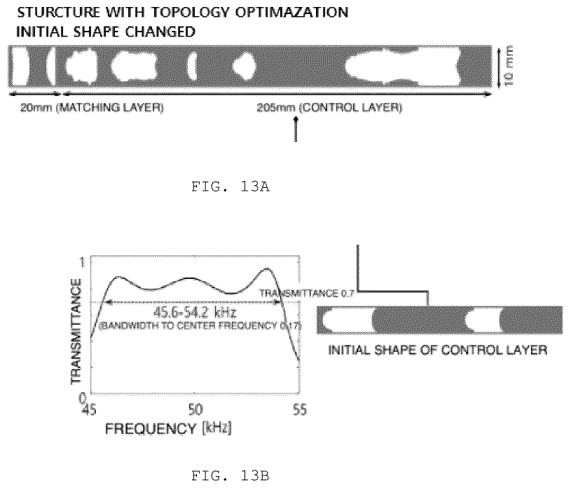

FIGS. 13A and 13B are views illustrating a structure according to a fourth example of the present disclosure. This example corresponds to the case when the initial design used for topology optimization and the total length of the structure are changed.

As illustrated in FIG. 13A, as the result of performing topology optimization using an initial shape in which several air voids are included in an aluminum base matrix of 225×10 mm², a matching layer including air voids having areas of 58.5 mm² and 25.5 mm² and a control layer including air voids having areas of 81.8 mm², 109 mm², 20.3 mm², 42.4 mm², and 341 mm² is designed. According to the structure of this example, as illustrated in FIG. 13B, acoustic energy of over about 70% passes through a barrier in a wide frequency hand of 45.6 to 54.2 kHz, this is about 0.17 times the center frequency, and it could be seen that it is possible to achieve both a broadband and high-transmission performance even though the initial shape and the length of the structure are changed.

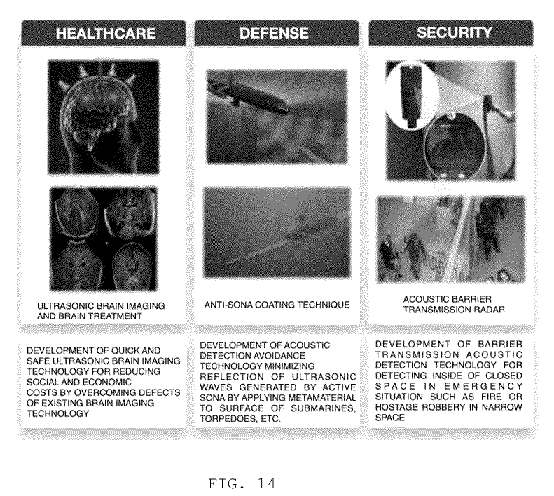

FIG. 14 is a view showing application of the present disclosure and as shown in the figure, the structure of the present disclosure can be used in various fields such as healthcare, defense, and security.

For example, a broadband high-transmission structure of the present disclosure can be used in the field of healthcare. The field of healthcare is as follows. It has been known that ultrasonic energy cannot pass through the skull of human brain due to acoustic impedance mismatching between the skull and the surrounding medium, so brain imaging or brain disease treatment using ultrasonic waves is impossible. When ultrasonic energy is transmitted to the brain region beyond the skull using the structure of the present disclosure, it is possible to provide quick and safe brain image diagnosis or brain disease treatment service for patients with emergency stroke for whom it is important to secure golden time or patients who require normal repetitive screening.

For example, the structure of the present disclosure can be used in the field of defense. It is very important to avoid a Sona system that detects the location of submarines or warships when performing marine exploration and military operations. By applying the structure according to an embodiment of the present disclosure to the surfaces of submarines, warships, torpedoes, etc., it is possible to use the structure as an acoustic detection avoidance technique of minimizing reflection of ultrasonic waves generated by an active Sona.

For example, the structure of the present disclosure can be used in the field of security. It is important to find out the accurate locations of people who require rescue in order to perform quick rescue at disaster sites hidden by thick concrete walls or metal structures, such as building collapse, ship sinking, and fire scenes, or crime scenes with a hostage situation. By developing a barrier transmission acoustic radar technology based on the structure of the present disclosure, it is possible to quickly find out and cope with situations in which the inside is visually blocked.

According to the present disclosure, it is possible to improve convenience of use and implement high transmittance in a wide frequency band by installing the structure, which is composed of an impedance matching layer minimizing reflection of wave energy between a background medium and an acoustic battier and a wave interference control layer for controlling multiple reflection in an acoustic barrier, ahead of the acoustic barrier.

Although exemplary embodiments of the present disclosure were described above with reference to the accompanying drawings, those skilled in the art would understand that the present disclosure may be implemented in various ways without changing the necessary features or the spirit of the prevent disclosure. Therefore, the embodiments described above are only examples and should not be construed as being limitative in all respects.

What is claimed is:

1. A structure that is attached to a front surface of an acoustic barrier for high transmission in a broadband frequency range, the structure comprising:
an impedance matching layer for transmitting a wave through the acoustic barrier by minimizing reflection of the wave due to the impedance mismatch between the acoustic barrier and an incident medium; and
a wave interference control layer for controlling interference due to multiple reflections within the acoustic barrier.

2. The structure of claim 1, wherein the impedance matching layer and the wave interference control layer have been staked in a traveling direction of the wave, and
the structure is configured such that the wave sequentially passes through the impedance matching layer, the wave interference control layer, and the acoustic barrier.

3. The structure of claim 2, wherein the wave interference control layer is attached to a front surface of the acoustic barrier.

4. The structure of claim 2, wherein the wave interference control layer is located at a predetermined distance from the front surface of the acoustic barrier.

5. The structure of claim 2, wherein the impedance matching layer and the wave interference control layer are each configured in a structure in which at least one or more void is formed in a base matrix.

6. The structure of claim 5, wherein the void of the impedance matching layer is formed in a structure that is symmetric with respect to a center line of the impedance matching layer.

7. The structure of claim 5, wherein the void of the impedance matching layer is formed in a structure that is asymmetric with respect to a center line of the impedance matching layer.

8. The structure of claim 5, wherein the void of the wave interference control layer is formed in a structure that is symmetric with respect to a center line of the wave interference control layer.

9. The structure of claim 5, wherein the void of the wave interference control layer is formed in a structure that is asymmetric with respect to a center line of the wave interference control layer.

10. The structure of claim 5, wherein the structures of the impedance matching layer and the wave interference control layer are each designed on the basis of a topology optimization algorithm.

11. The structure of claim 10, wherein the structures of the impedance matching layer and the wave interference control layer are each designed using the following equation,
$$G = {\sum }_{n = 1}^{∞} {\vert \frac{{I}_{t}}{{I}_{i}} \vert}_{f - {f}_{n}} \qquad [ Equation ]$$
(where, G is an objective function, Iᵢ is acoustic intensity of an incident wave, Iₜ is acoustic intensity of a transmission wave, f is a frequency of the incident wave, and fₙ is
$$\frac{( n - 1 ) ( {f}_{e} - {f}_{s} )}{n}$$
where fₛ and fₑ are start and end frequencies of the target frequency band).

12. The structure of claim 5, wherein the void is filled with air or other materials.

13. The structure of claim 5, wherein the impedance matching layer and the wave interference control layer are each configured in a structure of which a predetermined horizontal cross-sectional shape extends in a height direction.

14. The structure of claim 5, wherein the base matrix is made of a material the same as the acoustic barrier.

15. The structure of claim 5, wherein the base matrix is made of a material different from the acoustic barrier.

16. The structure of claim 1, wherein the impedance matching layer and the wave interference control layer are attached only to the front surface of the acoustic barrier and are not installed on a rear surface of the acoustic barrier.

17. A method of designing the structure of claim 1, the method comprising:
a first step of designing the impedance matching layer through a topology optimization; and
a second step of designing the wave interference control layer through the topology optimization.

18. The method of claim 17, further comprising:
a redesign step of correcting an initial design of the wave interference control layer obtained through the first step in consideration of input impedance at the incident interface.

19. The method of claim 18, wherein, in the redesign step, an initial design structure of the impedance matching layer designed in the first step is set as an initial shape and a final design of the impedance matching layer is designed through a topology optimization.
